(19) United States
(12) Patent Application Publication
(10) Pub. No.: US 2023/0118564 A1
(43) Pub. Date: Apr. 20, 2023

(54) POWER MODULE FOR PRODUCING STRUCTURE-BORNE SOUND, DEVICE FOR DETECTING AN IC PACKAGE DELAMINATION HAVING SUCH A POWER MODULE, AND METHOD FOR DETECTING AN IC PACKAGE DELAMINATION

(71) Applicant: Robert Bosch GmbH, Stuttgart (DE)

(72) Inventors: Josef Goeppert, Kusterdingen (DE); Karl Oberdieck, Neckartenzlingen (DE); Manuel Riefer, Reutlingen (DE); Sebastian Strache, Wannweil (DE)

(21) Appl. No.: 18/046,992

(22) Filed: Oct. 17, 2022

(30) Foreign Application Priority Data
Oct. 19, 2021 (DE) 10 2021 211 763.5

(51) Int. Cl. G01H 11/08; H01L 21/67; H01L 21/66

(52) U.S. Cl. CPC G01H 11/08; H01L 21/67253; H01L 22/12; H01L 22/34

(57) ABSTRACT

A power module for producing structure-borne sound. The power module includes: a control unit and a first substrate, the control unit being situated on the first substrate; at least one first power semiconductor and at least one second power semiconductor, the first substrate being situated on the at least one first power semiconductor and on the at least one second power semiconductor; a first metal connection, a second substrate, and a second metal connection, the first metal connection electrically connecting the first substrate and the second substrate, and the second metal connection being situated below the second substrate, wherein the second substrate has a piezoelectric material and the control unit is set up to excite the piezoelectric material of the second substrate so that a structure-borne sound signal is produced.

### CROSS REFERENCE

The present application claims the benefit under 35 U.S.C. § 119 of German Patent Application No. DE 10 2021 211 763.5 filed on Oct. 19, 2021, which is expressly incorporated herein by reference in its entirety.

### FIELD

The present invention relates to a power module for producing structure-borne sound, a device for detecting an IC package delamination having such a power module, and a method for detecting an IC package delamination.

### BACKGROUND INFORMATION

Power modules are subject to aging processes inside the integrated circuit packaging.

For the determination of the aging processes, it is conventional to ascertain the barrier layer temperature. Here, temperature-sensitive parameters acquired via evaluation circuits are evaluated.

A disadvantage of this is that additional components are used, and the temperature measurement via temperature-sensitive parameters is potentially susceptible to interference.

An object of the present invention is to overcome this disadvantage.

### SUMMARY

According to an example embodiment of the present invention, the power module for producing structure-borne sound has a control unit and a first substrate, the control unit being situated on the first substrate. In addition, the power module has at least one first power semiconductor and at least one second power semiconductor, the first substrate being situated on the at least one first power semiconductor and on the at least one second power semiconductor. The power module has a first metal connection, a second substrate, and a second metal connection. The first metal connection electrically connects the first substrate and the second substrate, and the second metal connection is situated below the second substrate. According to the present invention, the second substrate has a piezoelectric material, and the control unit is set up to excite the piezoelectric material of the second substrate so that a structure-borne sound signal is produced.

An advantage of this is that the structure-borne sound is produced inside the power module. In other words, the structure-borne sound production takes place in module-integrated fashion.

In a development of the present invention, the second substrate includes an AMB ceramic.

Here it is advantageous that the costs are low.

In a further development of the present invention, the control unit includes an ASIC.

An advantage of this is that the control unit is realized in application-specific fashion.

In a development of the present invention, the first substrate includes LTCC.

Here it is advantageous that the LTCC permits a high degree of integration density, and intelligent power modules can easily be produced.

According to an example embodiment of the present invention, the device for detecting an IC package delamination includes the power module according to the present invention and a MEMS sensor. According to the present invention, the MEMS sensor is situated on the first substrate of the power module, with a lateral distance from the control unit, the MEMS sensor being set up to acquire the produced structure-borne sound signal, and the control unit being set up to compare the acquired structure-borne sound signal to a reference value, an IC package delamination being recognized when the acquired structure-borne sound signal exceeds the reference value.

An advantage of this is that the detection takes place in module-internal fashion, i.e., without external components.

The method according to the present invention for detecting an IC package delamination, having a device according to the present invention for detecting the IC package delamination, includes the production of a structure-borne sound signal using a signal that is emitted by the control unit, and the acquiring of the structure-borne sound signal using the MEMS sensor. In addition, the method includes the comparison of the structure-borne sound signal to a reference value using the control unit, and the recognition of the IC package delamination when the acquired structure-borne sound signal exceeds the reference value.

In a development of the present invention, the signal has a resonant frequency of the second substrate.

An advantage of this is that the method is not susceptible to interference.

Further advantages result from the following description of exemplary embodiments of the present invention, and the figures.

### BRIEF DESCRIPTION OF THE DRAWINGS

In the following, the present invention is explained on the basis of preferred specific embodiments and the figures.

FIG. 1 shows a power module for producing structure-borne sound, according to an example embodiment of the present invention.

FIG. 2 shows a device for detecting an IC package delamination, according to an example embodiment of the present invention.

FIG. 3 shows a method for detecting an IC package delamination, according to an example embodiment of the present invention.

### DETAILED DESCRIPTION OF EXAMPLE EMBODIMENTS

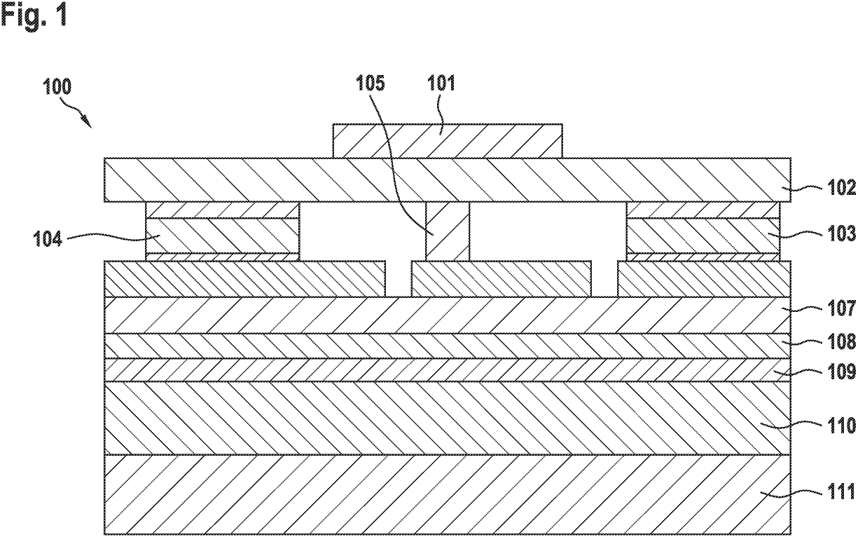

FIG. 1 shows a power module 100 for producing structure-borne sound. Power module 100 includes a control unit 101, a first substrate 102, at least one first power semiconductor 103, at least one second power semiconductor 104, a first metal connection 105, a second substrate 107, and a second metal connection 108. Second substrate 107 includes a piezoelectric material, for example AlN. Alternatively, second substrate 107 includes an AMB ceramic. Second substrate 107 is situated on second metal connection 108, second metal connection 108 acting as second electrode. First metal connection 105 is situated on second substrate 107, first metal connection 105 acting as first electrode. First power semiconductor 103 and second power semiconductor 104 are situated on second substrate 107. First substrate 102, which acts as bearer substrate, is situated on first power semiconductor 103 and on second power semiconductor 104. Control unit 101 is situated on first substrate 102. Control unit 101 includes for example an ASIC, and is set up to excite the piezoelectric material of second substrate 107 so that a structure-borne sound signal is produced. In other words, by applying the signal, in particular a sinusoidal signal or a square-wave signal, with an adequate amplitude, for example up to 100 V given an AlN thickness of 0.2 mm, second substrate 107 acts as a thickness vibrator and produces the structure-borne sound signal. The structure-borne sound signal can represent an item of runtime information, an item of amplitude information, an item of frequency information, or an item of phase information. The first substrate is for example an LTCC. Second metal connection 108 is situated on a cooling structure 110, and second metal connection 108 and cooling structure 110 are connected by a solder layer 109. Cooling structure 110 can be realized as a cooling plate or as a cooling element having a comb structure. Coolant fluid 111 is situated below cooling structure 110.

Power module 100 is used for example in the cleaning of the comb structure of cooling element structure 110. Alternatively, power module 100 is used to detect an IC package delamination.

The power module is used in drive inverters or in discrete components.

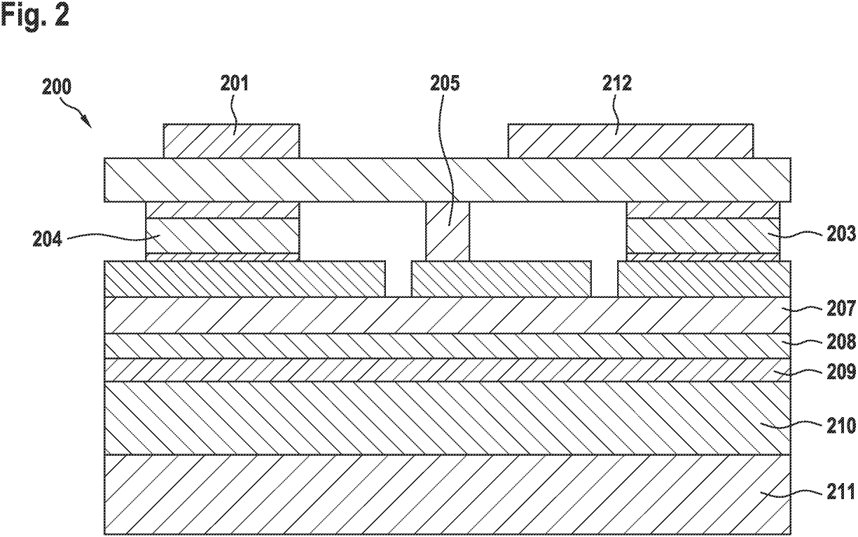

FIG. 2 shows a device 200 for detecting an IC package delamination. Device 200 includes the power module of FIG. 1. The reference characters of functionally identical elements in FIG. 2 have the same last two digits as in FIG. 1. In addition, device 200 has a MEMS sensor 212 that is situated on first substrate 202 with a lateral distance from control unit 201. MEMS sensor 212 and control unit 201 are for example electrically connected by a bond connection. MEMS sensor 212 is set up to acquire structure-borne sound signals. Control unit 201 is on the one hand set up to excite the piezoelectric material of second substrate 207 so that a structure-borne sound signal is produced, and on the other hand control unit 201 is set up to evaluate the structure-borne sound signals acquired by the MEMS sensor. Here, control unit 201 is set up to compare the acquired structure-borne sound signals, which include runtime information, frequency information, amplitude information, or phase information, to a reference value. If the acquired structure-borne sound signal exceeds the reference value, then an IC package delamination is recognized.

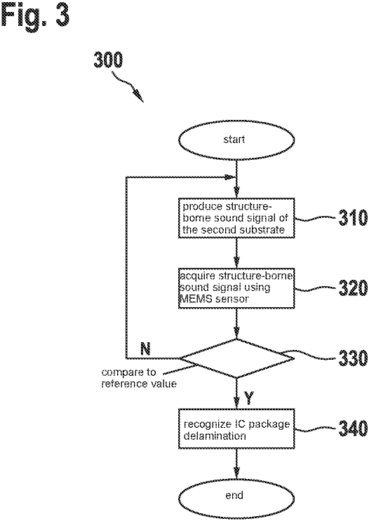

FIG. 3 shows a method 300 for detecting an IC package delamination using the device according to the present invention of FIG. 2. Method 300 starts with the production of a structure-borne sound signal of the second substrate, using a signal, in particular a sinusoidal signal or a square-wave signal, the signal being emitted by the control unit. (Step 310). In a following step 320, the structure-borne sound signal is acquired using the MEMS sensor. In a following step 330, the acquired structure-borne sound signal is compared to a reference value by the control unit. The reference value can be formed for example by trailing end measurement, finite element simulation, or laboratory measurement. If the acquired structure-borne sound signal exceeds the reference value, then in a following step 340 the IC package delamination is recognized. If the acquired structure-borne sound signal is smaller than the reference value, then method 300 ends, or starts again with step 310.

In an exemplary embodiment, the signal has a resonant frequency of the second substrate.

What is claimed is:

1. A power module for producing structure-borne sound, comprising:
a control unit and a first substrate, the control unit being situated on the first substrate;
at least one first power semiconductor and at least one second power semiconductor, the first substrate being situated on the at least one first power semiconductor and on the at least one second power semiconductor;
a first metal connection, a second substrate, and a second metal connection, the first metal connection electrically connecting the first substrate and the second substrate, and the second metal connection being situated below the second substrate;
wherein the second substrate has a piezoelectric material and the control unit is configured to excite the piezoelectric material of the second substrate so that a structure-borne sound signal is produced.

2. The power module as recited in claim 1, wherein the second substrate includes an AMB ceramic.

3. The power module as recited in claim 1, wherein the control unit includes an ASIC.

4. The power module as recited in claim 1, wherein the first substrate includes an LTCC.

5. A device configured to detect an IC package delamination, the device comprising:
a power module for producing structure-borne sound, the power module including:
a control unit and a first substrate, the control unit being situated on the first substrate,
at least one first power semiconductor and at least one second power semiconductor, the first substrate being situated on the at least one first power semiconductor and on the at least one second power semiconductor,
a first metal connection, a second substrate, and a second metal connection, the first metal connection electrically connecting the first substrate and the second substrate, and the second metal connection being situated below the second substrate,
wherein the second substrate has a piezoelectric material and the control unit is configured to excite the piezoelectric material of the second substrate so that a structure-borne sound signal is produced; and
a MEMS sensor situated on the first substrate at a lateral distance from the control unit, the MEMS sensor being configured to acquire the produced structure-borne sound signal, and the control unit being configured to compare the acquired structure-borne sound signal to a reference value, an IC package delamination being recognized if the acquired structure-borne sound signal exceeds the reference value.

6. A method for detecting an IC package delamination using a device including:
a power module for producing structure-borne sound, the power module including:
a control unit and a first substrate, the control unit being situated on the first substrate,
at least one first power semiconductor and at least one second power semiconductor, the first substrate being situated on the at least one first power semiconductor and on the at least one second power semiconductor,
a first metal connection, a second substrate, and a second metal connection, the first metal connection electrically connecting the first substrate and the second substrate, and the second metal connection being situated below the second substrate,
wherein the second substrate has a piezoelectric material and the control unit is configured to excite the piezoelectric material of the second substrate so that a structure-borne sound signal is produced; and
a MEMS sensor situated on the first substrate at a lateral distance from the control unit, the MEMS sensor being configured to acquire the produced structure-borne sound signal, and the control unit being configured to compare the acquired structure-borne sound signal to a reference value, an IC package delamination being recognized if the acquired structure-borne sound signal exceeds the reference value;
the method comprising the following steps:
producing the structure-borne sound signal of the second substrate using a sinusoidal signal that is emitted by the control unit;
acquiring the structure-borne sound signal using the MEMS sensor;
comparing the structure-borne sound signal to the reference value using the control unit; and
recognizing the IC package delamination based on the acquired structure-borne sound signal exceeding the reference value.

7. The method as recited in claim 6, wherein the sinusoidal signal has a resonant frequency of the second substrate.
